(19) United States
(12) Patent Application Publication
(10) Pub. No.: US 2009/0116273 A1
(43) Pub. Date: May 7, 2009

(54) SEMICONDUCTOR MEMORY DEVICE

(75) Inventor: Shinichiro SHIRATAKE, Yokohama-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/263,820

(22) Filed: Nov. 3, 2008

(30) Foreign Application Priority Data
Nov. 5, 2007 (JP) 2007-287577

(51) Int. Cl. G11C 5/06; G11C 11/24; G11C 11/22

(52) U.S. Cl. 365/72; 365/149; 365/145

(57) ABSTRACT

This disclosure concerns a memory including: unit cells having ferroelectric capacitors and cell transistors; two depletion transistors and two enhancement transistors serially connected between two adjacent unit series configurations configured by serially connecting the unit cells; four selective lines respectively connected to the gates of the two enhancement transistors and the two depletion transistors; word lines connected to the gates of the cell transistors; a bit line connected to the unit series configuration via at least one of the enhancement transistors and the depletion transistors; and a bit line contact connecting the bit line to at least one of the enhancement transistors and the depletion transistors, wherein in two of adjacent bit lines, the bit line contact connected to one of the two adjacent bit lines and the bit line contact connected to the other bit line are opposed to each other with respect to one of the selective lines.

### CROSS-REFERENCE TO RELATED APPLICATION

This application is based upon and claims the benefit of priority from the prior Japanese Patent Application No. 2007-287577, filed on Nov. 5, 2007, the entire contents of which are incorporated herein by reference.

### BACKGROUND OF THE INVENTION

1. Field of the Invention

The present invention relates to a semiconductor memory device, particularly relates to a ferroelectric memory with a ferroelectric capacitor.

2. Related Art

There have been developed series connected TC unit type ferroelectric memories that are memories which consist of series connected memory cells each having a cell transistor (T) having a source terminal and a drain terminal and a ferroelectric capacitor (C) in between said two terminals (hereafter named “Series connected TC unit type ferroelectric RAMs”). According to the series connected TC unit type ferroelectric memory (hereinafter, simply “ferroelectric memory”), one end of the series connected TC units (that configure a unit series configuration) is connected to a plate line, while the other end via a selective transistor to a bit line.

A plurality of the unit series configurations usually share a word line to configure a memory cell array. Data is transferred to one of two bit lines for the two unit series configurations sharing the word line, while a reference potential is transmitted to the other bit line by known methods. These two unit series configurations sharing the word line thus generate complementary data. For example, if bit lines with odd addresses are selected, the complementary data is transmitted to a pair of adjacent bit lines. At this time, bit lines with even addresses are not selected. Meanwhile, if the bit lines with the even addresses are selected, the complementary data is transmitted to a pair of adjacent bit lines. At this time, the bit lines with the odd addresses are not selected. To accomplish such a selective operation, block selective transistors are provided between the bit line and the unit series configuration.

The gate of the block selective transistor connected to the bit line with the even address (block selective line) is different from the gate of the block selective transistor connected to the bit line with the odd address (block selective line). Accordingly, the block selective transistor is controlled so as to select one of the bit line with the even address and the bit line with the odd address and not so as to select the other bit line.

For example, when the block selective transistor connected to the bit line with the even address is to be connected to the corresponding unit series configuration, the block selective line for the bit line with the odd address becomes an obstacle. To solve such a problem, a metal bridge (part designated by M1) is conventionally provided over the block selective line for the bit line with the odd address (FIG. 2 in Non-Patent Document 2).

However, the metal bridge requires contacts for connecting wirings and the unit series configuration and for connecting the wirings and the block selective transistor. These contacts need a certain area. Therefore, the metal bridge thus impairs the area efficiency of the ferroelectric memory.

### SUMMARY OF THE INVENTION

A semiconductor memory device according to an embodiment of the present invention comprises: a plurality of unit cells each having a ferroelectric capacitor and a cell transistor, the ferroelectric capacitor including a ferroelectric film between two electrodes, the cell transistor including a source and a drain connected to the two electrodes of the ferroelectric capacitor; two depletion transistors and two enhancement transistors serially connected between two adjacent unit series configurations each configured by serially connecting a plurality of the unit cells; four selective lines respectively connected to the gates of the two enhancement transistors and the two depletion transistors; a plurality of word lines connected to the gates of the cell transistors included in the unit series configuration; a bit line connected to the unit series configuration via at least one of the enhancement transistors and the depletion transistors; and a bit line contact connecting the bit line to at least one of the enhancement transistors and the depletion transistors, wherein

in two of adjacent bit lines, the bit line contact connected to one of the two adjacent bit lines and the bit line contact connected to the other bit line are opposed to each other with respect to one of the selective lines.

A semiconductor memory device according to an embodiment of the present invention comprises: a plurality of unit cells each having a ferroelectric capacitor and a cell transistor, the ferroelectric capacitor including a ferroelectric film between two electrodes, the cell transistor including a source and a drain connected to the two electrodes of the ferroelectric capacitor; two depletion transistors and two enhancement transistors serially connected between two adjacent unit series configurations each configured by serially connecting a plurality of the unit cells; four selective lines respectively connected to the gates of the two enhancement transistors and the two depletion transistors; a plurality of word lines connected to the gates of the cell transistors included in the unit series configuration; a bit line connected to the unit series configuration via at least one of the enhancement transistors and the depletion transistors; and a bit line contact connecting the bit line to at least one of the enhancement transistors and the depletion transistors, wherein

two adjacent unit series configurations forms a unit series configuration pair and a plurality of the unit series configuration pairs are arranged along a first bit line of the bit lines, and

an arrangement order of the two enhancement transistors and the two depletion transistors between a first unit series configuration pair of the unit series configuration pairs connected to the first bit line is different from an arrangement order of the two enhancement transistors and the two depletion transistors between a second unit series configuration pair, the second unit series configuration pair is connected to the first bit line and is adjacent to the first unit series configuration pair.

### BRIEF DESCRIPTION OF THE DRAWINGS

FIG. 1 is a circuit diagram showing the configuration of a ferroelectric memory according to an embodiment of the present invention;

FIG. 2 is a cross-sectional view showing the configurations of two adjacent unit series configurations USC1 and USC2, the enhancement transistors ET1 and ET2, and the depletion transistors DT1 and DT2 between the unit series configurations USC1 and USC2;

FIG. 3 is a cross-sectional view showing the configurations of two adjacent unit series configurations USC3 and USC4, the enhancement transistors ET1 and ET2, and the depletion transistors DT1 and DT2 between the unit series configurations USC3 and USC4;

FIG. 4 is a cross-sectional view showing the configurations of two adjacent unit series configurations USC5 and USC6, the enhancement transistors ET1 and ET2, and the depletion transistors DT1 and DT2 between the unit series configurations USC5 and USC6;

FIG. 5 is a cross-sectional view showing the configurations of two adjacent unit series configurations USC7 and USC8, the enhancement transistors ET1 and ET2, and the depletion transistors DT1 and DT2 between the unit series configurations USC7 and USC8;

FIG. 6 is a schematic diagram showing the layout of the block selective lines BS1 to BS4 and bit line contacts BLCs;

FIG. 7 is a simplified diagram combining the circuit diagram shown in FIG. 1 and the layout diagram shown in FIG. 6;

FIG. 8 shows unit serial configurations USC 9 to USC16 that are connected to the bit lines BL1 to BL4 and subsequent to the plate lines PL5 to PL8 shown in FIG. 7;

FIG. 9 shows unit series configurations USC17 to USC24 that are connected to the bit lines BL1 to BL4 and subsequent to the plate lines PL9 to PL12 shown in FIG. 8;

FIG. 10 shows unit series configurations USC25 to USC32 that are connected to the bit lines BL1 to BL4 and subsequent to the plate lines PL13 to PL16 shown in FIG. 9;

FIG. 11 a circuit diagram showing a comparative example; and

FIG. 12 a layout chart showing a comparative example.

### DETAILED DESCRIPTION OF THE INVENTION

Embodiments of the present invention will be explained below in detail with reference to the accompanying drawings. Note that the present invention is not limited thereto.

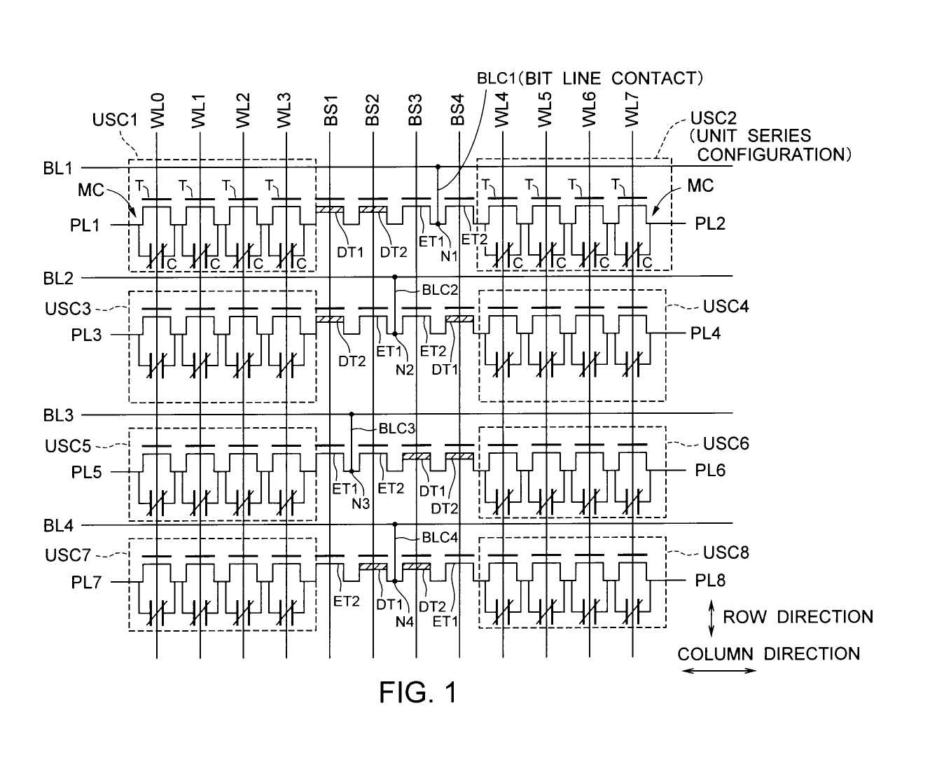

FIG. 1 is a circuit diagram showing the configuration of a ferroelectric memory according to an embodiment of the present invention. The ferroelectric memory according to this embodiment is a series connected TC unit type ferroelectric memory. A memory cell MC serving as a unit cell is formed of a ferroelectric capacitor C including a ferroelectric film between two electrodes and a cell transistor T including a source and drain connected to the two electrodes of the ferroelectric capacitor C, respectively. A plurality of the memory cells MCs are serially connected to each other so as to configure a unit series configuration USC. In the present embodiment, four memory cells MCs are serially connected to each other so as to configure the unit series configuration USC.

A plurality of the unit series configurations USCs are arranged two-dimensionally on a semiconductor substrate in a matrix shape. A word line WL extends in a row direction and is connected to the gate of the cell transistor T arranged in the row direction. In the present embodiment, since the unit series configuration USC has four memory cells MCs, four word lines WLs are provided for every unit series configuration USC. A bit line BL extends in a column direction substantially perpendicular to the row direction for unit series configurations USCs arranged in the column direction.

Two depletion transistors DT1 and DT2 and two enhancement transistors ET1 and ET2 are serially connected between two unit series configurations USCs (hereinafter, also “unit series configuration pair”) that are connected to the same bit line BL and adjacent to each other in the column direction. The depletion transistors DT1 and DT2 are transistors that are always in a conductive state regardless of gate voltage. The enhancement transistors ET1 and ET2 are transistors that are in a non-conductive state when a potential is not applied to their gates and becomes a conductive state by the application of the potential to the gates. The transistors DT1, DT2, ET1, and ET2 can be n-type MISFETs (Metal-Insulator-Semiconductor Field-Effect Transistors) or p-type MISFETs. The gates of the transistors DT1, DT2, ET1, and ET2 are connected respectively to four block selective lines BS1 to BS4. The block selective lines BS1 to BS4 are connected to the same bit line BL, provided between two unit series configurations USCs adjacent to each other in the column direction, and extend in the row direction.

For example, with reference to FIG. 1, in a unit series configuration pair of USC1 and USC2, a first bit line BL1 is connected via the enhancement transistor ET1 and two depletion transistors DT1 and DT2 to the unit series configuration USC1 and via the enhancement transistor ET2 to the unit series configuration USC2. In a unit series configuration pair of USC3 and USC4, a second bit line BL2 adjacent to the first bit line BL1 in the row direction is connected via the enhancement transistor ET1 and the depletion transistor DT2 to the unit series configuration USC3 and via the enhancement transistor ET2 and the depletion transistor DT1 to the unit series configuration USC4. In a unit series configuration pair of USC5 and USC6, a third bit line BL3 adjacent to the second bit line BL2 in the row direction is connected via the enhancement transistor ET1 to the unit series configuration USC5 and via the enhancement transistor ET2 and two depletion transistors DT1 and DT2 to the unit series configuration USC6. In a unit series configuration pair of USC7 and USC8, a fourth bit line BL4 adjacent to the third bit line BL3 in the row direction is connected via the depletion transistor DT1 and the enhancement transistor ET2 to the unit series configuration USC7 and via the depletion transistor DT2 and the enhancement transistor ET1 to the unit series configuration USC8.

A bit line contact BLC1 connects between the bit line BL1 and a node N1. The node N1 is placed between the enhancement transistors ET1 and ET2 provided between the unit series configurations USC1 and USC2. A bit line contact BLC2 connects between the bit line BL2 and a node N2. The node N2 is placed between the enhancement transistors ET1 and ET2 provided between the unit series configurations USC3 and USC4. A bit line contact BLC3 connects between the bit line BL3 and a node N3. The node N3 is placed between the enhancement transistors ET1 and ET2 provided between the unit series configurations USC5 and USC6. A node N4 is placed between the depletion transistors DT1 and DT2 provided between the unit series configurations USC7 and USC8.

The unit series configurations USC1 to USC8 are connected to plate lines PL1 to PL8 at their one ends. The plate lines PL1 to PL8 are held at a fixed potential at a standby state.

Each of the bit lines BL1 to BL4 is connected via at least one enhancement transistor to the unit series configuration. Unless the enhancement transistor ET1 or ET2 is made conductive, the bit lines BL1 to BL4 cannot be connected to the unit series configurations USCs.

For example, when the block selective line BS1 is driven, the enhancement transistor ET1 between the unit series configurations USC5 and USC6 becomes the conductive state, so that the bit line BL3 is connected to the unit series configuration USC5. In this case, the enhancement transistor ET2 between the unit series configurations USC7 and USC8 also becomes the conductive state, so that the bit line BL4 is connected to the unit series configuration USC7. At this time, an activation potential is applied to one of the plate lines PL5 and PL7 and the other line maintains the fixed potential in the standby state. For example, when the plate line PL5 is activated, the data of the memory cells MCs included in the unit series configuration USC5 connected to the bit line BL3 is transferred to the bit line BL3. Meanwhile, since the plate line PL7 is not activated, the data of the memory cells MCs included in the unit series configuration USC7 connected to the bit line BL4 is not transferred to the bit line BL4.

When the block selective line BS2 is driven, the enhancement transistor ET1 between the unit series configurations USC3 and USC4 becomes the conductive state, so that the bit line BL2 is connected to the unit series configuration USC3. The enhancement transistor ET2 between the unit series configurations USC5 and USC6 also becomes the conductive state, so that the bit line BL3 is connected to the unit series configuration USC6. At this time, the activation potential is applied to one of the plate lines PL3 and PL6 and the other line maintains the fixed potential in the standby state. For example, when the plate line PL3 is activated, the data of the memory cells MCs included in the unit series configuration USC3 connected to the bit line BL2 is transferred to the bit line BL2. Meanwhile, because the plate line PL6 is not activated, the data of the memory cells MCs included in the unit series configuration USC6 connected to the bit line BL3 is not transferred to the bit line BL3.

When the block selective line BS3 is driven, the enhancement transistor ET1 between the unit series configurations USC1 and USC2 becomes the conductive state, so that the bit line BL1 is connected to the unit series configuration USC1. In this case, the enhancement transistor ET2 between the unit series configurations USC3 and USC4 also becomes the conductive state, so that the bit line BL2 is connected to the unit series configuration USC4. At this time, the activation potential is applied to one of the plate lines PL1 and PL4 and the other line maintains the fixed potential in the standby state. When the plate line PL1 is activated, the data of the memory cells MCs included in the unit series configuration USC1 connected to the bit line BL1 is transferred to the bit line BL1. Meanwhile, because the plate line PL4 is not activated, the data of the memory cells MCs included in the USC4 connected to the bit line BL2 is not transferred to the bit line BL2.

When the block selective line BS4 is driven, the enhancement transistor ET2 between the unit series configurations USC1 and USC2 becomes the conductive state, so that the bit line BL1 is connected to the unit series configuration USC2. In this case, the enhancement transistor ET1 between the unit series configurations USC7 and USC8 also becomes the conductive state, so that the bit line BL4 is connected to the unit series configuration USC8. At this time, the activation potential is applied to one of the plate lines PL2 and PL8 and the other line maintains the fixed potential in the standby state. For example, when the plate line PL2 is activated, the data of the memory cells MCs included in the unit series configuration USC2 connected to the bit line BL1 is transferred to the bit line BL1. Meanwhile, because the plate line PL8 is not activated, the data of the memory cells MCs included in the USC8 connected to the bit line BL4 is not transferred to the bit line BL4.

The bit lines BL1 to BL4 are connected to sense amplifiers (not shown). The sense amplifier compares the data to be transmitted to the bit lines BL1 to BL4 to reference data in order to detect data.

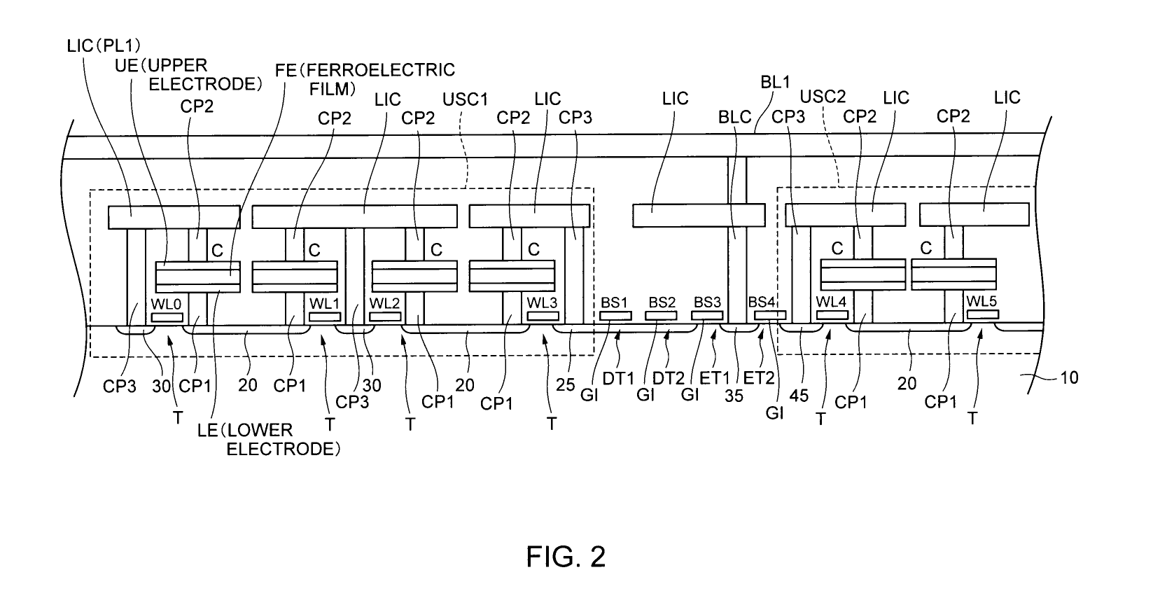

FIG. 2 is a cross-sectional view showing the configurations of two adjacent unit series configurations USC1 and USC2, the enhancement transistors ET1 and ET2, and the depletion transistors DT1 and DT2 between the unit series configurations USC1 and USC2. The cell transistor T is formed on a silicon substrate 10. The adjacent transistors T share a source layer 20 or a drain layer 30. The cell transistor T can be an n-type MISFET or a p-type MISFET. The diffusion layers 20 and 30 can be source layers or drain layers. A gate dielectric film GI is provided on a channel between the diffusion layers 20 and 30. The word line WL (gate electrode) is provided on the gate dielectric film GI. The word line WL extends in the row direction as shown in FIG. 1. An interlayer dielectric film ILD is provided around the word line WL.

The ferroelectric capacitor C is provided above the cell transistor T with the interlayer dielectric film ILD interposed therebetween. The ferroelectric capacitor C has a lower electrode LE, upper electrode UE, and ferroelectric film FE sandwiched between the lower electrode LE and upper electrode UE. The lower electrode LE is made of, e.g., iridium Ir. The ferroelectric film FE is made of, e.g., PZT(Pb(Zrₓ, Ti_{1-X})O₃) or SBT(SrBi₂Ta₂O₉). The upper electrode is made of, e.g., iridium oxide IrO₂.

The lower electrode LE is connected via a contact plug CP1 to the diffusion layer 20. The upper electrode UE is connected via a contact plug CP2 to a local wiring LIC. The local wiring LIC is connected via a contact plug CP3 to the diffusion layer 30. The local wiring LIC between the unit series configurations USC1 and USC2 is connected to a bit line contact BLC. The bit line BL1 is connected via the bit line contact BLC1 to the diffusion layer 35. The bit line contact BLC1 is provided between the block selective lines BS3 and BS4.

The block selective lines BS1 to BS4 are provided between the unit series configurations USC1 and USC2 on the silicon substrate 10 with the respective gate dielectric films GIs interposed therebetween. The block selective lines BS1 to BS4 function as gate electrodes for the transistors DT1, DT2, ET1, and ET2. Note that the diffusion layer 25 extends from under the contact plug CP3 at an end of the unit series configuration USC1 through the channel immediately below the block selective lines BS1 and BS2 to reach immediately below the block selective line BS3. The depletion transistors DT1 and DT2 that have the block selective lines BS1 and BS2 as the respective gate electrodes are thus formed. The diffusion layer is not formed at the channel immediately below the block selective lines BS3 and BS4 and the impurity density of that channel is relatively low. The enhancement transistors ET1 and ET2 that have the block selective lines BS3 and BS4 as the respective gate electrodes are thus formed. The bit line BL1 drives the block selective line BS3 (i.e., turns the enhancement transistor ET1 on) so as to be connected via the diffusion layer 25 (i.e., via the depletion transistors DT1 and DT2) to the contact plug CP3 at the end of the USC1. The bit line BL1 drives the block selective line BS4 (i.e., turns the enhancement transistor ET2 on) so as to be connected via the diffusion layer 45 to the contact plug CP3 at an end of the unit series configuration USC2.

With reference to the cross-section in FIG. 2, the depletion transistor DT1, the depletion transistor DT2, the enhancement transistor ET1, and the enhancement transistor ET2 are provided in this order for the block selective lines BS1 to BS4, respectively. The arrangement order of the depletion transistors DT1 and DT2 and the enhancement transistors ET1 and ET2 shown in FIG. 2 (DT1, DT2, ET1, and ET2) will be referred to as a first arrangement.

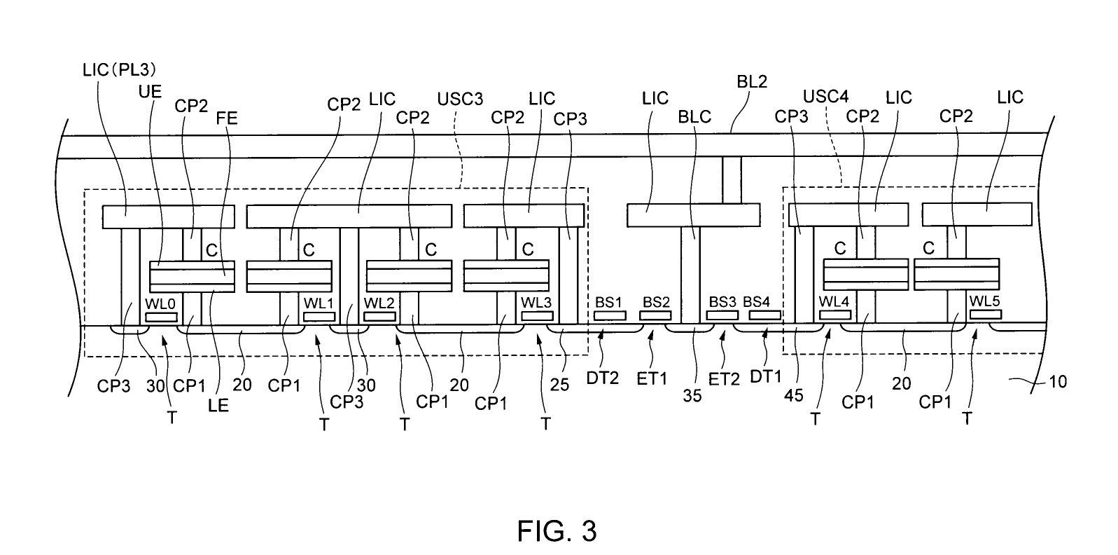

FIG. 3 is a cross-sectional view showing the configurations of two adjacent unit series configurations USC3 and USC4, the enhancement transistors ET1 and ET2, and the depletion transistors DT1 and DT2 between the unit series configurations USC3 and USC4. While the cross-section along the bit line BL1 is shown in FIG. 2, the cross-section along the bit line BL2 is shown in FIG. 3.

With reference to the cross-section of FIG. 3, the depletion transistor DT2, the enhancement transistor ET1, the enhancement transistor ET2, and the depletion transistor DT1 are provided in this order for the block selective lines BS1 to BS4, respectively. The arrangement order of the depletion transistors DT1 and DT2 and enhancement transistors ET1 and ET2 shown in FIG. 3 (DT2, ET1, ET2, and DT1) will be referred to as a second arrangement. According to this arrangement, the bit line contact BLC is placed between the block selective lines BS2 and BS3. That is, for the bit lines BL1 and BL2 adjacent to each other, the bit line contact BLC connected to the bit line BL1 and the bit line contact BLC connected to the bit line BL2 are opposed to each other with respect to the block selective line BS3.

Driving the block selective line BS2 (i.e., turning the enhancement transistor ET1 on) allows the bit line BL2 to be connected via the diffusion layer 25 (i.e., via the depletion transistor DT2) to the contact plug CP3 at an end of the unit series configuration USC3. Driving the block selective line BS3 (i.e., turning the enhancement transistor ET2 on) allows the bit line BL2 to be connected via the diffusion layer 45 (i.e., via the depletion transistor DT1) to the contact plug CP3 at an end of the unit series configuration USC4.

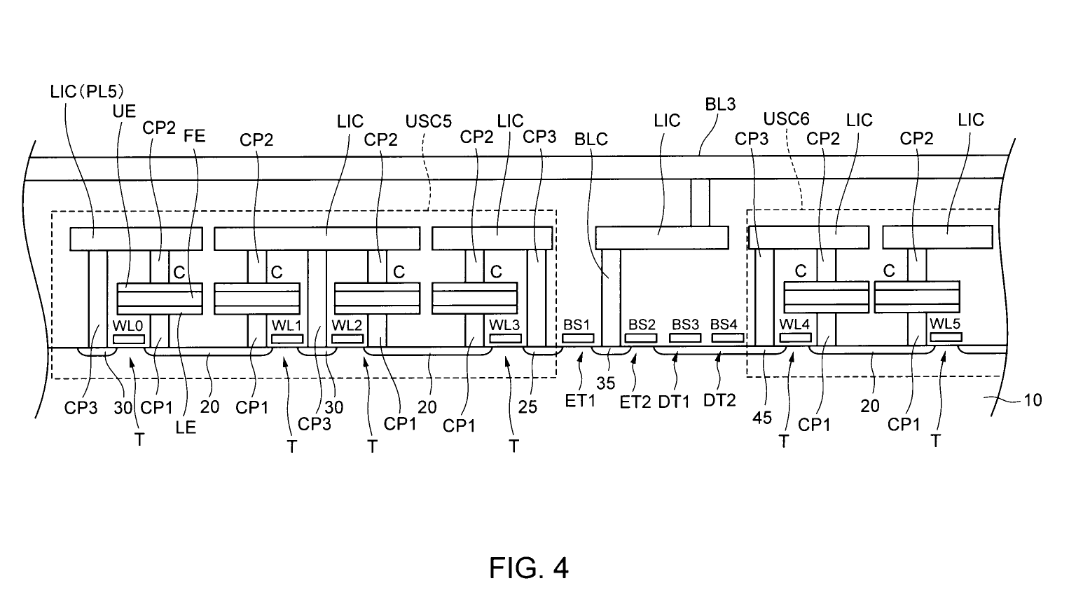

FIG. 4 is a cross-sectional view showing the configurations of two adjacent unit series configurations USC5 and USC6, the enhancement transistors ET1 and ET2, and the depletion transistors DT1 and DT2 between the unit series configurations USC5 and USC6. FIG. 4 shows the cross-section along the bit line BL3. With reference to the cross-section in FIG. 4, the enhancement transistors ET1 and ET2, depletion transistor DT1, and depletion transistor DT2 are provided in this order for the block selective lines BS1 to BS4, respectively. The arrangement order of the depletion transistors DT1 and DT2 and enhancement transistors ET1 and ET2 shown in FIG. 4 (ET1, ET2, DT1, and DT2) will be referred to as a third arrangement. According to this arrangement, the bit line contact BLC is provided between the block selective lines BS1 and BS2. That is, for the bit lines BL2 and BL3 adjacent to each other, the bit line contact BLC connected to the bit line BL2 and the bit line contact BLC connected to the bit line BL3 are opposed to each other with respect to the block selective line BS2.

Driving the block selective line BS1 (i.e., turning the enhancement transistor ET1 on) allows the bit line BL3 to be connected via the diffusion layer 25 to the contact plug CP3 at an end of the unit series configuration USC5. Driving the block selective line BS2 (i.e., turning the enhancement transistor ET2 on) allows the bit line BL3 to be connected via the diffusion layer 45 (i.e., via the depletion transistors DT1 and DT2) to the contact plug CP3 at an end of the unit series configuration USC6.

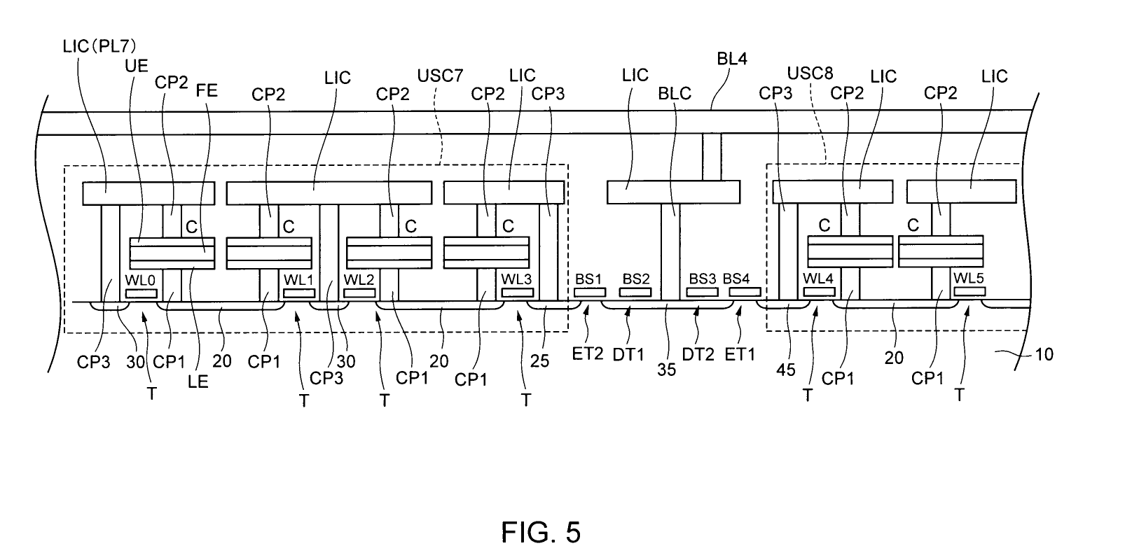

FIG. 5 is a cross-sectional view showing the configurations of two adjacent unit series configurations USC7 and USC8, the enhancement transistors ET1 and ET2, and the depletion transistors DT1 and DT2 between the unit series configurations USC7 and USC8. FIG. 5 shows the cross-section along the bit line BL4. With reference to the cross-section in FIG. 5, the enhancement transistor ET2, the depletion transistors DT1 and DT2, and the enhancement transistor ET1 are provided in this order for the block selective lines BS1 to BS4, respectively. The arrangement order of the depletion transistors DT1 and DT2 and the enhancement transistors ET1 and ET2 shown in FIG. 5 (ET2, DT1, DT2, and ET1) will be referred to as a fourth arrangement. According to this arrangement, the bit line contact BLC is provided between the block selective lines BS2 and BS3. That is, for the bit lines BL3 and BL4 adjacent to each other, the bit line contact BLC connected to the bit line BL3 and the bit line contact BLC connected to the bit line BL4 are opposed to each other with respect to the block selective line BS2.

Driving the block selective line BS1 (i.e., turning the enhancement transistor ET2 on) allows the bit line BL4 to be connected via the diffusion layer 25 (i.e., via the depletion transistor DT1) to the contact plug CP3 at an end of the unit series configuration USC7. Driving the block selective line BS4 (i.e., turning the enhancement transistor ET1 on) allows the bit line BL4 to be connected via the diffusion layer 45 (i.e., via the depletion transistor DT2) to the contact plug CP3 at an end of the unit series configuration USC8.

As described above, according to the present embodiment, the enhancement transistor functioning as a selective transistor is connected to the unit series configuration using not metal bridges but the depletion transistors DT1 and DT2. Because the metal bridge is not used in the present embodiment, contacts for the metal bridge are unnecessary. Accordingly, the ferroelectric memory according to the present embodiment has thus superior area efficiency and microfabrication property.

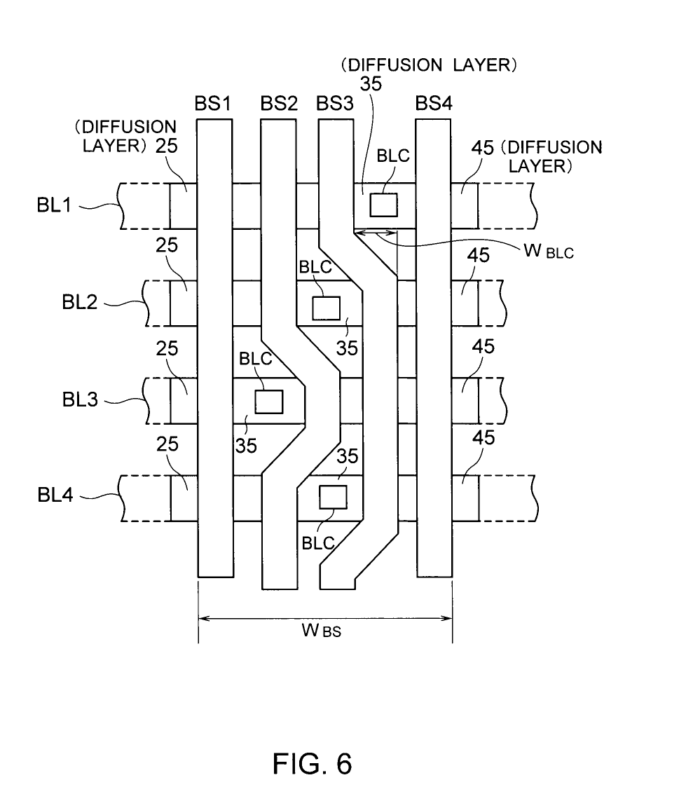

FIG. 6 is a schematic diagram showing the layout of the block selective lines BS1 to BS4 and bit line contacts BLCs. As shown in FIG. 6, for adjacent bit lines, the bit line contacts BLCs are placed so as to sandwich a block selective line. The first to fourth arrangements appear equally in this order along the word line WL. Assume that the first to fourth arrangements are designated by A1 to A4, respectively. The first to fourth arrangements will be appeared along the word line WL in the order of A1, A2, A3, A4, A3, A2, A1, A2, A3, A4, A3, A2 onward repeatedly in this embodiment. The block selective lines BS1 and BS4 are formed substantially linearly, and only one of the block selective lines BS2 and BS3 is bent between a space between the bit lines. That is, in the bit lines BL1 to BL4, the enhancement transistors ET1 and ET2 and depletion transistors DT1 and DT2 are arranged as shown in FIGS. 2 to 5. The number of block selective lines that should be bent between spaces between the bit lines is decreased while maintaining the selective function of the unit series configurations USC1 to USC8. As the number of the block selective lines that should be bent is decreased, the layout width WBS of the block selective lines BS1 to BS4 is reduced. Since the layout width WBS of the block selective lines BS1 to BS4 can be reduced, the ferroelectric memory according to the present embodiment has superior microfabrication property.

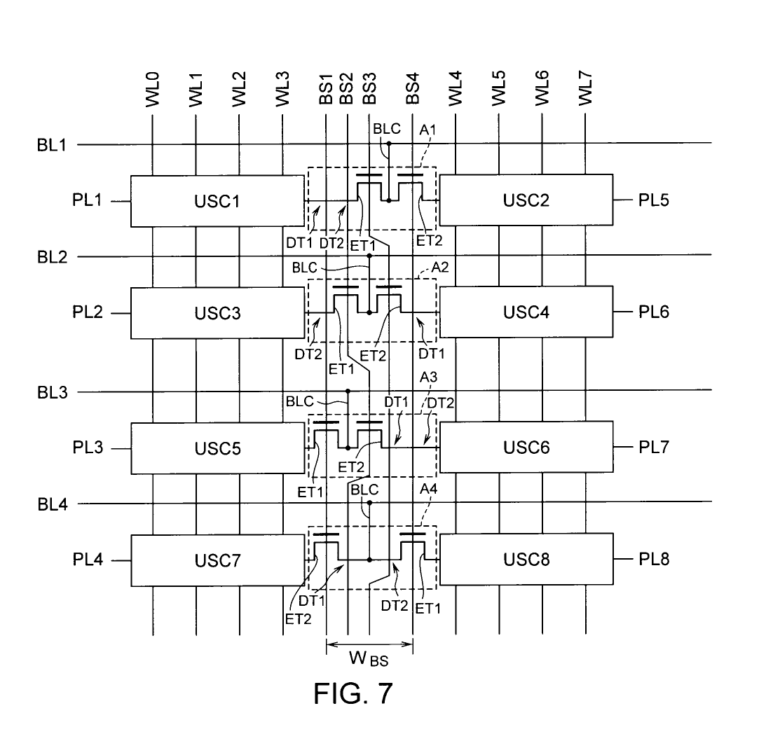

FIG. 7 is a simplified diagram combining the circuit diagram shown in FIG. 1 and the layout diagram shown in FIG. 6. With reference to FIG. 7, the first to fourth arrangements A1 to A4 are applied to the bit lines BL1 to BL4, respectively.

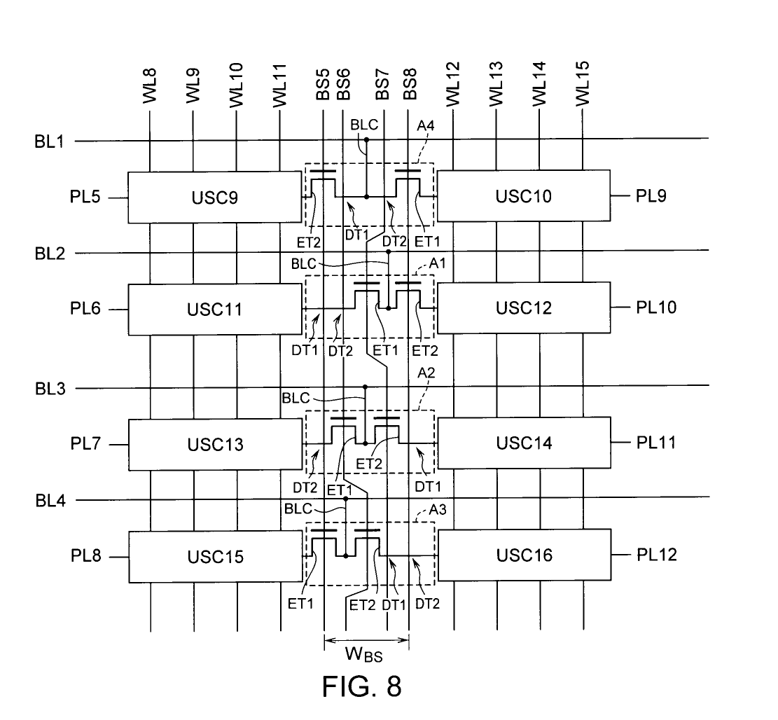

FIG. 8 shows unit serial configurations USC 9 to USC16 that are connected to the bit lines BL1 to BL4 and subsequent to the plate lines PL5 to PL8 shown in FIG. 7. That is, the configuration of FIG. 8 is subsequent to that of FIG. 7 in the bit line direction. The unit serial configurations USC9, USC11, USC13, and USC15 share the plate lines PL5 to PL8 with the unit serial configurations USC2, USC4, USC6, and USC8 shown in FIG. 7. The configurations of the unit serial configurations USC9 to USC16 are the same as those of the unit serial configurations USC1 to USC8.

The block selective lines BS5 to BS8 shown in FIG. 8 are formed within the same layout width WBS as that for the block selective lines BS1 to BS4 shown in FIG. 7. However, the arrangements of the enhancement transistors ET1 and ET2 and depletion transistors DT1 and DT2 shown in FIG. 8 are different from those of FIG. 7. That is, with reference to FIG. 8, the fourth arrangement A4 is applied to the bit line BL1, the first arrangement A1 to the bit line BL2, the second arrangement A2 to the bit line BL3, and the third arrangement A3 to the bit line BL4. Accordingly, the positions of bit line contacts BLCs of the bit lines BL1 to BL4 in FIG. 7 are different from those of FIG. 8.

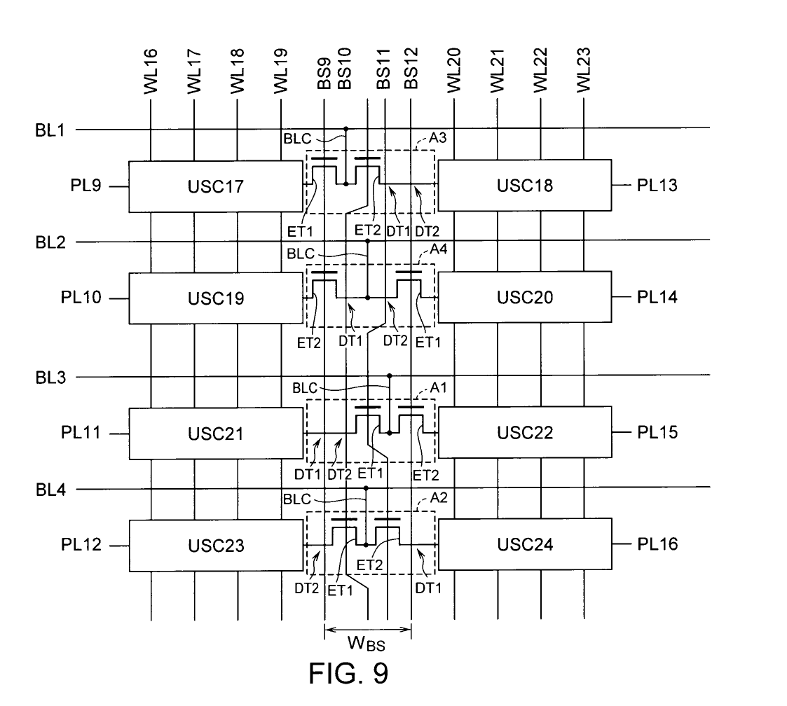

FIG. 9 shows unit series configurations USC17 to USC24 that are connected to the bit lines BL1 to BL4 and subsequent to the plate lines PL9 to PL12 shown in FIG. 8. That is, the configuration of FIG. 9 is subsequent to that of FIG. 8 in the bit line direction. The unit series configurations USC17, USC19, USC21, and USC23 share the plate lines PL9 to PL12 with the unit series configurations USC10, USC12, USC14, and USC16 shown in FIG. 8. The configurations of the unit series configurations USC17 to USC24 can be the same as those of the unit series configurations USC1 to USC8.

The block selective lines BS9 to BS12 shown in FIG. 9 are formed within the width WBS. However, the arrangements of the enhancement transistors ET1 and ET2 and depletion transistors DT1 and DT2 shown in FIG. 9 are different from those of FIGS. 7 and 8. That is, with reference to FIG. 9, the third arrangement A3 is applied to the bit line BL1, the fourth arrangement A4 to the bit line BL2, the first arrangement A1 to the bit line B13, and the second arrangement A2 to the bit line BL4. Accordingly, the positions of bit line contacts BLCs of the bit lines BL1 to BL4 in FIG. 9 are different from those of FIGS. 7 and 8.

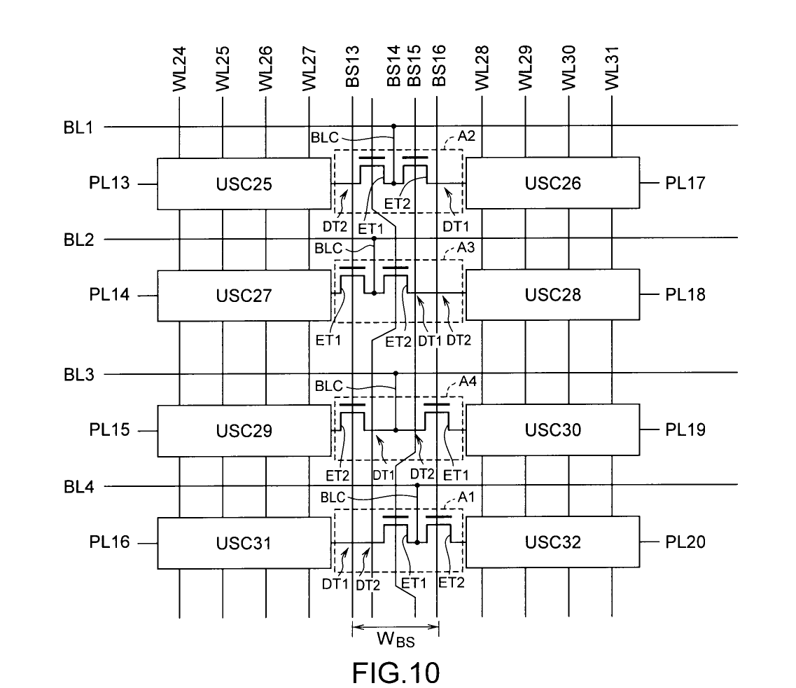

FIG. 10 shows unit series configurations USC25 to USC32 that are connected to the bit lines BL1 to BL4 and subsequent to the plate lines PL13 to PL16 shown in FIG. 9. That is, the configuration of FIG. 10 is subsequent to that of FIG. 9 in the bit line direction. The unit series configurations USC25, USC27, USC29, and USC31 share the plate lines PL13 to PL16 with the unit series configurations USC18, USC20, USC22, and USC24 shown in FIG. 9. The configurations of the unit series configurations USC25 to USC32 can be the same as those of the unit series configurations USC1 to USC8.

The block selective lines BS13 to BS16 shown in FIG. 10 are formed within the width WBS. However, the arrangements of the enhancement transistors ET1 and ET2 and depletion transistors DT1 and DT2 shown in FIG. 10 are different from those of FIGS. 7 to 9. That is, with reference to FIG. 10, the second arrangement A2 is applied to the bit line BL1, the third arrangement A3 to the bit line BL2, the fourth arrangement A4 to the bit line BL3, and the first arrangement A1 to the bit line BL4. Accordingly, the positions of bit line contacts BLCs of the bit lines BL1 to BL4 in FIG. 10 are different from those of FIGS. 7 to 9.

The same configuration as that of FIG. 7 is connected to the plate lines PL17 to PL20 shown in FIG. 10. The ferroelectric memory according to the present embodiment is configured so that the configurations of FIGS. 7 to 10 are connected to each other in the bit line direction and word line direction.

Only in the fourth arrangement A4 of the first to fourth arrangements A1 to A4, the bit line BL is connected via the bit line contact BLC directly to the depletion transistors DT1 and DT2.

In the first to third arrangements A1 to A3, the bit lines BLs are connected to the enhancement transistors ET1 and ET2. Therefore, unless the enhancement transistors ET1 and ET2 are turned on, the bit lines BLs are not connected to the depletion transistors DT1 and DT2.

When an increased number of depletion transistors are directly connected to the bit line BL, the parasitic capacitance of the bit line BL is increased. The bit line BL with increased parasitic capacitance requires large power to be driven. Therefore, to reduce the consumption power and increase the operating speed, the number of the depletion transistors directly connected to the bit line BL is preferably as low as possible. To enhance the S/N ratio (Signal-to-Noise ratio), the number of the depletion transistors directly connected to the bit line BL is preferably as low as possible.

With reference to FIGS. 7 to 10, the first to fourth arrangements A1 to A4 appear equally and repeatedly in the bit line BL1. For example, the first to fourth arrangements A1 to A4 appears such as A1, A2, A3, A4, A3, A2, A1, A2, A3, A4, A3, A2 onward. That is, the fourth arrangement A4 appears only in a unit series configuration pair of four unit series configuration pairs. Therefore, the parasitic capacitance of the bit line BL according to the present embodiment is not so increased.

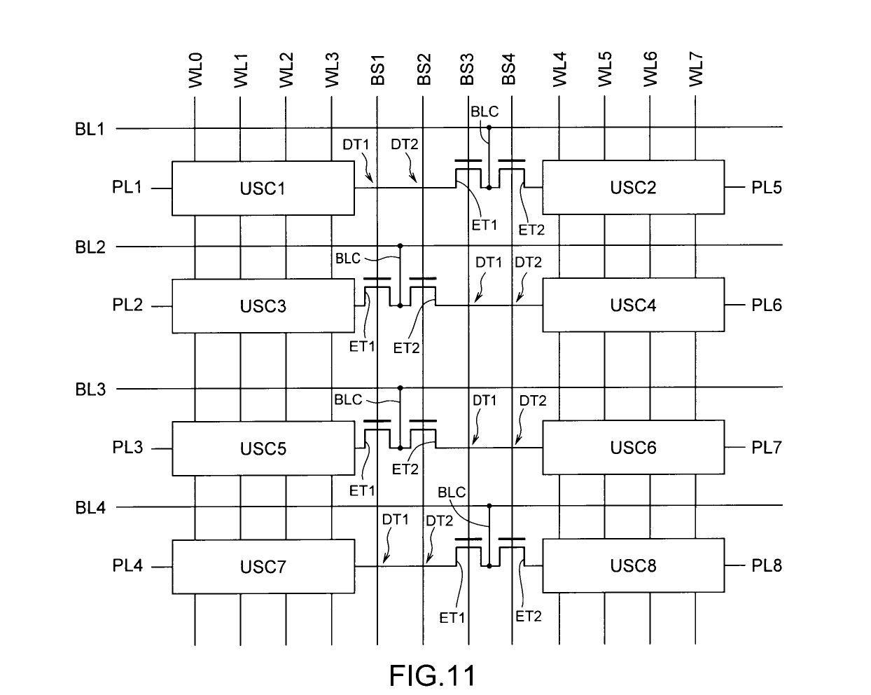

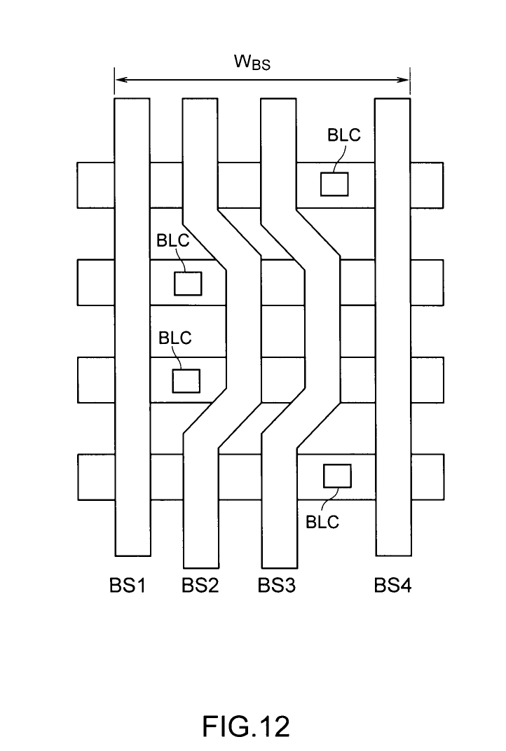

For example, as shown in a comparative example of FIG. 11, when the bit line BL is connected via the enhancement transistor to the depletion transistor in all arrangements, two bit line contacts BLCs for two adjacent bit lines are placed so as to sandwich two block selective lines. In this case, two block selective lines BS2 and BS3 must be bent between two adjacent bit lines BL1 and BL2 as shown in FIG. 12. To bend these two block selective lines between two adjacent bit lines, the width WBS of the block selective lines BS1 to BS4 needs to be increased. Therefore, the area efficiency of the entire ferroelectric memory becomes inferior. That is, the configuration shown in FIGS. 11 and 12 is inferior to the present embodiment in terms of area efficiency.

According to the present embodiment, although the parasitic capacitance of the bit line seems to be larger than that of the comparative example, the length of the bit line itself is reduced since the distance between a pair of the unit series configurations (width WBS within which block selective lines are arranged) is decreased. Shorter bit line allows smaller parasitic capacitance. Accordingly, increases in parasitic capacitance of two depletion transistors DT1 and DT2 in the fourth arrangement A4 can be suppressed to some extent by the shortened bit line. Therefore, the parasitic capacitance of the bit line according to the present embodiment is not so increased as compared to the comparative example.

When the chip size of the ferroelectric memory is considered as important, this embodiment is superior to the comparative example. When the capacity of bit line of the ferroelectric memory is considered as important, the bit line capacity of the embodiment is compared to that of the comparative example and either of them will be selected. Note that the comparative example shown in FIGS. 11 and 12 is not a conventional technique but merely a comparative example.

While the first to fourth arrangements A1 to A4 are applied to every four bit lines BLs in the embodiment, the first to fourth arrangements A1 to A4 can be applied to every eight bit lines BLs. For example, the arrangements A1, A1, A2, A2, A3, A3, A4, and A4 are applied to eight bit lines BLs, respectively. The first to fourth arrangements A1 to A4 appear periodically for every eight bit lines BLs. Of course, the first to fourth arrangements A1 to A4 can be applied to every twelve or more bit lines BLs.

In addition, the order of the first to fourth arrangements A1 to A4 can be changed in adjacent bit lines BLs.

1. A semiconductor memory device comprising:
a plurality of unit cells each having a ferroelectric capacitor and a cell transistor, the ferroelectric capacitor including a ferroelectric film between two electrodes, the cell transistor including a source and a drain connected to the two electrodes of the ferroelectric capacitor;
two depletion transistors and two enhancement transistors serially connected between two adjacent unit series configurations each configured by serially connecting a plurality of the unit cells;
four selective lines respectively connected to the gates of the two enhancement transistors and the two depletion transistors;
a plurality of word lines connected to the gates of the cell transistors included in the unit series configuration;
a bit line connected to the unit series configuration via at least one of the enhancement transistors and the depletion transistors; and
a bit line contact connecting the bit line to at least one of the enhancement transistors and the depletion transistors, wherein
in two of adjacent bit lines, the bit line contact connected to one of the two adjacent bit lines and the bit line contact connected to the other bit line are opposed to each other with respect to one of the selective lines.

2. The semiconductor memory device according to claim 1, wherein number of selective lines bent between two adjacent bit lines is one.

3. The semiconductor memory device according to claim 1, wherein
in two adjacent first unit series configurations, a first bit line of the bit lines is connected via one enhancement transistor and two depletion transistors to one of the first unit series configurations, and the first bit line is connected via one enhancement transistor to the other first unit series configuration;
in two adjacent second unit series configurations, a second bit line is connected via one enhancement transistor and one depletion transistor to one of the second unit series configurations, and the second bit line is connected via one enhancement transistor and one depletion transistor to the other second unit series configuration;
in two adjacent third unit series configurations, a third bit line is connected via one enhancement transistor to one of the third unit series configurations, and the third bit line is connected via one enhancement transistor and two depletion transistors to the other third unit series configuration; and
in two adjacent fourth unit series configurations, a fourth bit line is connected via one enhancement transistor and one depletion transistor to one of the fourth unit series configurations, and the fourth bit line is connected via one enhancement transistor and one depletion transistor to the other fourth unit series configuration.

4. The semiconductor memory device according to claim 1, wherein arrangement orders of the two enhancement transistors and two depletion transistors are repeated equally for the same bit line.

5. The semiconductor memory device according to claim 2, wherein arrangement orders of the two enhancement transistors and two depletion transistors are repeated equally for the same bit line.

6. The semiconductor memory device according to claim 3, wherein arrangement orders of the two enhancement transistors and two depletion transistors are repeated equally for the same bit line.

7. The semiconductor memory device according to claim 1, wherein arrangement orders of the two enhancement transistors and two depletion transistors are repeated equally in an extending direction of the word line.

8. The semiconductor memory device according to claim 2, wherein arrangement orders of the two enhancement transistors and two depletion transistors in the unit series configuration pairs are repeated equally in an extending direction of the word line.

9. The semiconductor memory device according to claim 3, wherein arrangement orders of the two enhancement transistors and two depletion transistors in the unit series configuration pairs are repeated equally in an extending direction of the word line.

10. A semiconductor memory device comprising:
a plurality of unit cells each having a ferroelectric capacitor and a cell transistor, the ferroelectric capacitor including a ferroelectric film between two electrodes, the cell transistor including a source and a drain connected to the two electrodes of the ferroelectric capacitor;
two depletion transistors and two enhancement transistors serially connected between two adjacent unit series configurations each configured by serially connecting a plurality of the unit cells;
four selective lines respectively connected to the gates of the two enhancement transistors and the two depletion transistors;
a plurality of word lines connected to the gates of the cell transistors included in the unit series configuration;
a bit line connected to the unit series configuration via at least one of the enhancement transistors and the depletion transistors; and
a bit line contact connecting the bit line to at least one of the enhancement transistors and the depletion transistors, wherein
two adjacent unit series configurations forms a unit series configuration pair and a plurality of the unit series configuration pairs are arranged along a first bit line of the bit lines, and
an arrangement order of the two enhancement transistors and the two depletion transistors between a first unit series configuration pair of the unit series configuration pairs connected to the first bit line is different from an arrangement order of the two enhancement transistors and the two depletion transistors between a second unit series configuration pair, the second unit series configuration pair is connected to the first bit line and is adjacent to the first unit series configuration pair.

11. The semiconductor memory device according to claim 10, wherein in the first unit series configuration pair, the two enhancement transistors and the two depletion transistors are arranged in an order of a first depletion transistor, a second depletion transistor, a first enhancement transistor, and a second enhancement transistor, and the bit line contact is provided between the first enhancement transistor and the second enhancement transistor (first arrangement),
in the second unit series configuration pair, the two enhancement transistors and the two depletion transistors are arranged in an order of the second depletion transistor, the first enhancement transistor, the second enhancement transistor, and the first depletion transistor, and the bit line contact is provided between the first enhancement transistor and the second enhancement transistor (second arrangement),
in a third unit series configuration pair adjacent to the second unit series configuration pair, the two enhancement transistors and the two depletion transistors are arranged in an order of the first enhancement transistor, the second enhancement transistor, the first depletion transistor, and the second depletion transistor, and the bit line contact is provided between the first enhancement transistor and the second enhancement transistor (third arrangement), and
in a fourth unit series configuration pair adjacent to the third unit series configuration pair, the two enhancement transistors and the two depletion transistors are arranged in an order of the second enhancement transistor, the first depletion transistor, the second depletion transistor, and the first enhancement transistor, and the bit line contact is provided between the first depletion transistor and the second depletion transistor (fourth arrangement).

12. The semiconductor memory device according to claim 11, wherein when the first to the fourth arrangements are denoted by A1 to A4, the two enhancement transistors and the two depletion transistors are arranged in a direction the word line extends such as A1, A2, A3, A4, A3, A2, A1, A2, A3, A4, A3, A2 onward.

13. The semiconductor memory device according to claim 10, wherein arrangement orders of the two enhancement transistors and two depletion transistors in the unit series configuration pairs are repeated equally for the same bit line.

14. The semiconductor memory device according to claim 11, wherein arrangement orders of the two enhancement transistors and two depletion transistors in the unit series configuration pairs are repeated equally for the same bit line.

15. The semiconductor memory device according to claim 12, wherein arrangement orders of the two enhancement transistors and two depletion transistors in the unit series configuration pairs are repeated equally for the same bit line.

16. The semiconductor memory device according to claim 10, wherein arrangement orders of the two enhancement transistors and two depletion transistors in the unit series configuration pairs are repeated equally in an extending direction of the word line.

17. The semiconductor memory device according to claim 11, wherein arrangement orders of the two enhancement transistors and two depletion transistors in the unit series configuration pairs are repeated equally in an extending direction of the word line.

18. The semiconductor memory device according to claim 12, wherein arrangement orders of the two enhancement transistors and two depletion transistors in the unit series configuration pairs are repeated equally in an extending direction of the word line.

19. The semiconductor memory device according to claim 13, wherein arrangement orders of the two enhancement transistors and two depletion transistors in the unit series configuration pairs are repeated equally in an extending direction of the word line.
